(19) United States
(12) Patent Application Publication
(10) Pub. No.: US 2017/0219657 A1
(43) Pub. Date: Aug. 3, 2017

(54) ONLINE BATTERY CAPACITY ESTIMATION UTILIZING PASSIVE BALANCING

(71) Applicant: Robert J. Vovos, Vestal, NY (US)

(72) Inventor: Robert J. Vovos, Vestal, NY (US)

(73) Assignee: BAE SYSTEMS Controls Inc., Endicott, NY (US)

(21) Appl. No.: 15/009,249

(22) Filed: Jan. 28, 2016

(51) Int. Cl. G01R 31/36; H02J 7/00

(52) U.S. Cl. CPC G01R 31/3658; G01R 31/3648; G01R 31/3682; G01R 31/3679; H02J 7/0014

(57) ABSTRACT

A method, battery module, an energy storage device and a power management system is provided. The capacity of the module and energy storage device is determined during current balancing between cells of the module. The capacity is subsequently used to control power to and from the energy storage device to maintain the energy storage device within a predetermined range of the maximum capacity of the energy storage device. The determined capacity is used as a maximum capacity for the energy storage device.

### FIELD OF THE DISCLOSURE

This disclosure relates to a system, an energy storage device, a battery module and a method for determining capacity of the energy storage device. This disclosure also relates to systems, methods and programs for controlling power to and from an energy storage device based on the determined capacity.

### BACKGROUND

Energy storage devices including storage devices for vehicles such as hybrid electric vehicles have a nominal maximum capacity at installation. The maximum capacity of the energy storage device decreases over time. The rate of degradation changes based on temperature. Further, the rate of degradation is affected by how power is controlled to and from the energy storage device. For example, the more an energy storage device is drained below a set value or charged above of set value, the rate of degradation typically increases and thus the maximum capacity is reduced. Use of the energy storage device also affects the rate of degradation. Energy storage devices that are used more frequently will typically have a lower maximum capacity than the energy storage device having the same nominal maximum capacity at installation that is used less frequently.

In a system, such as either a series or parallel hybrid electric vehicle, knowledge of a current maximum capacity is needed to control the power to and from the energy storage device. Power management is based at least on the current state of charge of the battery. The current state of charge is relative to the current maximum capacity.

### SUMMARY

Disclosed is a method comprising enabling balancing of current in a plurality of cells of a battery module by controlling a switch within each cell. Each cell includes a balance resistor. For each cell, the method further comprises storing a voltage of the respective cell at a predetermined time after the balancing is enabled. The voltage is sensed using a precision voltage sensor in each cell. For each cell, the method further comprises determining a cell current, for a predetermined period of time beginning at the predetermined time after the balancing is enabled, detecting a voltage of the respective cell at the end of the predetermined period of time, determining a change in a state of charge of the respective cell based on a change in the voltage over the predetermined period of time and a slope of an open circuit voltage curve and determining a cell capacity based on the change in the state of charge and the determined cell current for the predetermined period of time.

The method further comprises storing, in the memory of the battery microprocessor the determined cell capacity for each cell and transmitting, a module capacity to a battery controller for an energy storage device. The lowest determined cell capacity for the plurality of cells, is the module capacity for the battery module.

Also disclosed is a battery module for an energy storage device. The module comprises a plurality of cells, balancing circuit and a microprocessor. The balancing circuitry is associated with each cell. The balancing circuitry comprises a balance resistor, a balance switch and a precision voltage sensor.

The balance switch is configured to close to enable current balancing between the plurality of cells and open to disable the current balancing. The balance switch is connected in series with the balance resistor. The precision voltage sensor is configured to detect a voltage of the cell.

The microprocessor includes a memory. The memory has open circuit voltage curve stored therein. The open circuit voltage curve indicates a relationship between a voltage of a respective cell and a state of charge for the respective cell.

The microprocessor configured to receive a signal instructing current balancing for the plurality of cells from a battery microprocessor for the energy storage device, control the balance switch associated with each cell to close to enable current balancing, and store in the memory, a first voltage of each of the plurality of cells. The first voltage is detected by a respective precision voltage sensor at a predetermined time after the balancing is enabled. The microprocessor is further configured to determine, for each cell of the plurality of cells, a cell current, for a predetermined period of time beginning at the predetermined time after the balancing is enabled, and store in the memory, a second voltage of each of the plurality of cells. The second voltage is detected by the respective precision voltage sensor at the end of the predetermined period of time. The microprocessor is further configured to determine, for each cell of the plurality of cells, a change in a state of charge of the respective cell based on a slope of the open voltage curve stored in memory and a change in the voltage over the predetermined period of time determined from the stored first voltage and the second voltage, determine, for each cell of the plurality of cells, a cell capacity based on the change in the state of charge and the determined cell current for the predetermined period of time, store, in the memory, the determined cell capacity for each cell and transmit, a module capacity to the battery microprocessor. The lowest determined cell capacity for the plurality of cells, is the module capacity for the battery module.

Also disclosed is an energy storage device. The energy storage device comprises a switch, a battery current sensor, a battery microprocessor and a plurality of battery modules.

The switch is configured to either electrically isolate the energy storage device from a powertrain of a vehicle or electrically couple the energy storage device to the powertrain.

The battery current sensor is configured to detect current in the energy storage device.

The battery microprocessor is configured to control the switch to open to electrically isolate or close to electrically couple based on a signal received from a system controller. When the battery microprocessor receives a signal from the system controller that the vehicle is off, the battery microprocessor controls the switch to open. The battery microprocessor monitors the current detected by the battery current sensor.

Each of the plurality of modules comprises a plurality of cells. Each cell is associated with balancing circuitry. The balancing circuitry comprises a balance resistor, a balance switch; and a precision voltage sensor.

The balance switch is configured to close to enable current balancing between the plurality of cells and open to disable the current balancing. The balance switch is connected in series with the balance resistor. The precision voltage sensor is configured to detect a voltage of the cell.

Each of the plurality of battery modules further comprises a microprocessor including a memory. The memory has an open circuit voltage curve stored therein. The open circuit voltage curve indicates a relationship between a voltage of a respective cell and state of charge for the respective cell. The plurality of battery modules are coupled to the battery microprocessor. After the battery microprocessor determines that the current of the energy storage device is zero, the battery microprocessor issues an instruction to the microprocessor in each of the plurality of modules to enable current balancing.

The microprocessor in each of the plurality of modules is configured to receive the instruction from the battery microprocessor to enable current balancing for the plurality of cells, control the balance switch associated with each cell to close to enable current balancing and store in the memory, a first voltage of each of the plurality of cells. The first voltage is detected by a respective precision voltage sensor at a predetermined time after the balancing is enabled. The microprocessor in each of the plurality of modules is configured to determine, for each cell of the plurality of cells, a cell current, for a predetermined period of time beginning at the predetermined time after the balancing is enabled and store in the memory, a second voltage of each of the plurality of cells. The second voltage is detected by the respective precision voltage sensor at the end of the predetermined period of time. The microprocessor in each of the plurality of modules is configured to determine, for each cell of the plurality of cells, a change in a state of charge of the respective cell based on a slope of the open voltage curve stored in memory and a change in the voltage over the predetermined period of time determined from the stored first voltage and the second voltage, determine, for each cell of the plurality of cells, a cell capacity based on the change in the state of charge and the determined cell current for the predetermined period of time and store, in the memory the determined cell capacity for each cell. The microprocessor in each of the plurality of modules is configured to transmit, a module capacity to the battery microprocessor. The lowest determined cell capacity for the plurality of cells, is the module capacity for the battery module.

The battery microprocessor is further configured to store each of the transmitted module capacities in a memory of the battery microprocessor and determine a capacity for the energy storage device. The capacity for the energy storage device is the lowest determined module capacity for the plurality of modules. The battery microprocessor is further configured to transmit the determined battery capacity to the system controller.

Also disclosed is a power management system for a vehicle comprising a system controller configured to control power to and from an energy storage device. The system controller is coupled to the energy storage device.

The energy storage device comprises a switch, a battery current sensor, a battery microprocessor and a plurality of battery modules.

The switch is configured to either electrically isolate the energy storage device from a powertrain of a vehicle or electrically couple the energy storage device to the powertrain.

The battery current sensor is configured to detect current in the energy storage device.

The battery microprocessor is configured to control the switch to open to electrically isolate or close to electrically couple based on a signal received from a system controller.

When the vehicle is turned off, the system controller is configured to issue a signal to the battery microprocessor and when the battery microprocessor receives the signal from the system controller that the vehicle is off, the battery microprocessor controls the switch to open, and the battery microprocessor monitors the current detected by the battery current sensor.

Each of the plurality of battery modules comprises a plurality of cells. Each cell is associated with balancing circuitry. The balancing circuitry comprises a balance resistor, a balance switch; and a precision voltage sensor.

The balance switch is configured to close to enable current balancing between the plurality of cells and open to disable the current balancing. The balance switch is connected in series with the balance resistor. The precision voltage sensor is configured to detect a voltage of the cell.

Each of the plurality of battery modules further comprises a microprocessor including a memory. The memory has an open circuit voltage curve stored therein. The open circuit voltage curve indicates a relationship between a voltage of a respective cell and state of charge for the respective cell. The plurality of battery modules are coupled to the battery microprocessor. After the battery microprocessor determines that the current of the energy storage device is zero, the battery microprocessor issues an instruction to the microprocessor in each of the plurality of modules to enable current balancing.

The microprocessor in each of the plurality of modules is configured to receive the instruction from the battery microprocessor to enable current balancing for the plurality of cells, control the balance switch associated with each cell to close to enable current balancing and store in the memory, a first voltage of each of the plurality of cells. The first voltage is detected by a respective precision voltage sensor at a predetermined time after the balancing is enabled. The microprocessor in each of the plurality of modules is configured to determine, for each cell of the plurality of cells, a cell current, for a predetermined period of time beginning at the predetermined time after the balancing is enabled and store in the memory, a second voltage of each of the plurality of cells. The second voltage is detected by the respective precision voltage sensor at the end of the predetermined period of time. The microprocessor in each of the plurality of modules is configured to determine, for each cell of the plurality of cells, a change in a state of charge of the respective cell based on a slope of the open voltage curve stored in memory and a change in the voltage over the predetermined period of time determined from the stored first voltage and the second voltage, determine, for each cell of the plurality of cells, a cell capacity based on the change in the state of charge and the determined cell current for the predetermined period of time and store, in the memory the determined cell capacity for each cell. The microprocessor in each of the plurality of modules is configured to transmit, a module capacity to the battery microprocessor. The lowest determined cell capacity for the plurality of cells, is the module capacity for the battery module.

The battery microprocessor is further configured to store each of the transmitted module capacities in a memory of the battery microprocessor, determine a capacity for the energy storage device and transmit the determined battery capacity to the system controller. The capacity for the energy storage device is the lowest determined module capacity for the plurality of modules.

The system controller is further configured to store the determined battery capacity received from the battery microprocessor. When the vehicle is turned on subsequently, the system controller is further configured to control power to and from the energy storage device using the determined battery capacity as a maximum capacity for the energy storage device to maintain the energy storage device within a predetermined range of the maximum capacity.

### BRIEF DESCRIPTION OF THE DRAWINGS

FIG. 1 illustrates an energy storage device in accordance with aspects of the disclosure;

FIG. 2 illustrates a battery module with balancing circuitry in accordance with aspects of the disclosure;

FIGS. 3 and 4 illustrate a method for determining a capacity of an energy storage device in accordance with aspects of the disclosure;

FIG. 5 illustrates an example of a open circuit voltage curve storage stored in a memory of a Microprocessor in accordance with aspects of the disclosure;

FIG. 6 illustrates a block diagram of a parallel hybrid electric vehicle in accordance with aspects of the disclosure;

FIG. 7 illustrates a block diagram of a series hybrid electric vehicle in accordance with aspects of the disclosure; and

FIG. 8 illustrates a method for controlling power to and from an energy storage devices using the determined capacity in accordance with aspects of the disclosure.

### DETAILED DESCRIPTION

### Definitions and Notations

Vocᵢ(t) Open Circuit Cell Voltage of Cell number i at time t
Qᵢ Charge of cell i
I_{cell}_{_}ᵢ Current in cell i
SoCᵢ State of Charge of cell i
Cᵢ Amp Hour Capacity of cell i
Vocₘ Module open circuit voltage
I_{cpu} Current drawn from module to power Microprocessor
P_{cpu} Power drawn my Microprocessor

### R_{balance} Resistance of Balancers

I_{balance}_{_}ᵢ Balancing current of cell i

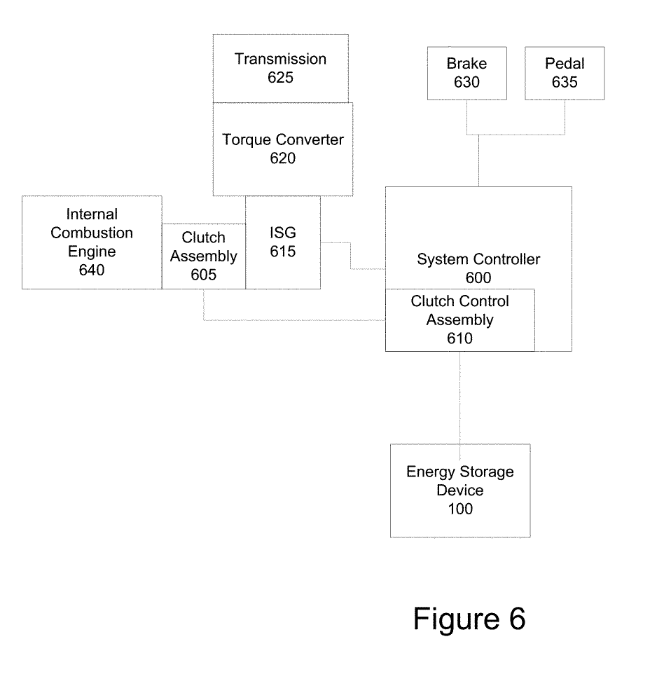

In accordance with aspects of the disclosure, each battery module is capable of determining a module capacity during the time that current balancing in the cells of the module is occurring and report the same to a battery controller 120 for the Energy Storage Device 100. In turn, the Battery Controller 120 determines the capacity of the Energy Storage Device 100 and reports the same to a System Controller (described later in FIG. 6). The System Controller subsequently uses the determined capacity of the Energy Storage Device 100 as the maximum capacity of the Energy Storage Device when controlling the power to and from the Energy Storage Device 100.

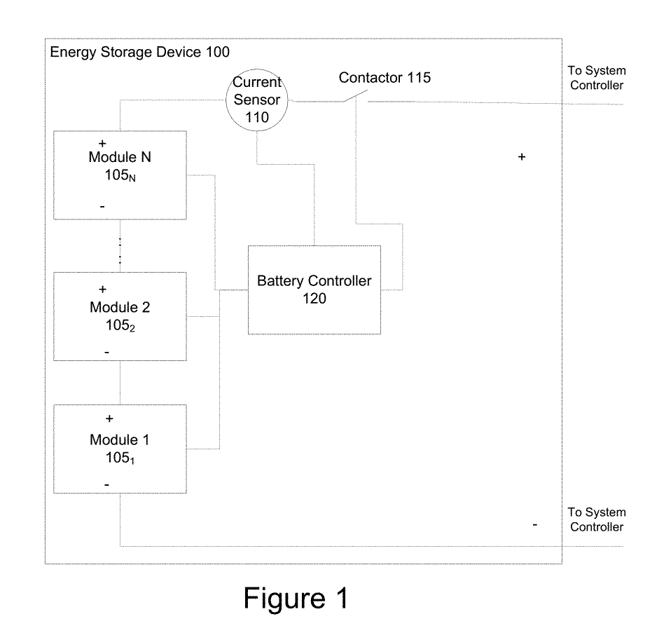

FIG. 1 illustrates a block diagram of an energy storage device 100 in accordance with aspects of the disclosure. The Energy Storage Device 100 includes a Battery Controller 120, a plurality of battery modules (collectively battery modules 105), a Current Sensor 110 and a Contactor 115. The number of battery modules 105(n) is based on the needed maximum capacity of the Energy Storage Device 100. The battery modules 105 are connected in series. The Battery Controller 120 is coupled to each of the battery modules 105. The Battery Controller 120 includes a memory (not shown). The memory stores a history of the capacities for each module, capacity for the Energy Storage Device and the state of health for each module. In another aspect of the disclosure, the memory can also store the state of health for Energy Storage Device. The Battery Controller 120 is coupled to the System Controller and can receive control information from the System Controller and report the capacity for the Energy Storage Device. In another aspect of the disclosure, the Battery Controller 120 can also report the state of health for the Energy Storage Device to the System Controller.

The Battery Controller 120 is also coupled to a Current Sensor 110. The Current Sensor 110 is configured to detect current through the Energy Storage Device 100. The Current Sensor 110 is placed in series with the plurality of battery modules 105. The Current Sensor 110 reports the detected current to the Battery Controller 120.

The Energy Storage Device 100 also includes a Contactor 115. The Contactor 115 is configured to open to isolate the Energy Storage Device 110 from the powertrain or close to couple the Energy Storage Device 110 to the powertrain. The Battery Controller 120 controls the state of the Contactor 115 based on information received from the System Controller. The Contactor 115 can be a Single Pole Single Throw Relay. In another aspect of the disclosure a semiconductor switch can be used, such as a MOSFET.

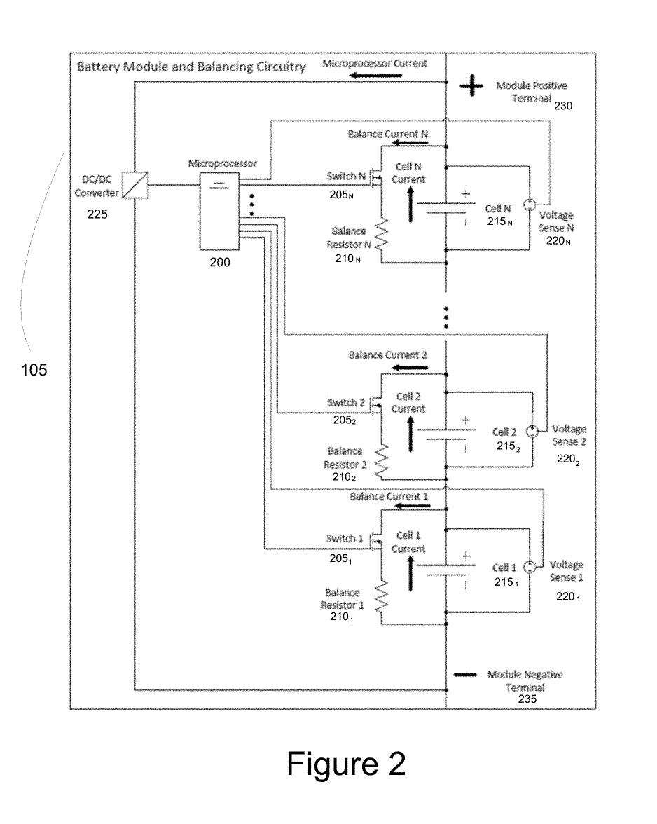

FIG. 2 illustrates a battery module with balancing circuitry in accordance with aspects of the disclosure. Each module 105 includes a Microprocessor 200 (refer to as Microprocessor 200 or Microprocessor 200). The Microprocessor 200 includes a memory (not shown). The memory stores an open circuit voltage curve indicating a relationship between a voltage of a respective cell and a state of charge for the respective cell and sensed voltages for each of the cells (and associated time). The memory can also store the determined cell capacity for each of a plurality of cells.

Each module 105 includes a plurality of cells (215₁-215_{N}). The cells 215₁-215_{N} are associated with respective balancing circuitry including a high precision voltage sensor (220₁-220_{N}). The high precision voltage sensor is coupled to the respective terminals of the cell (+terminal and −terminal). For example, a high precision voltage sensor 220₁ is coupled to the positive and negative terminal of the cell 1 215₁ The precision of the voltage sensor impacts the determined capacity. Therefore, the high precision voltage sensor 220 is configured to detect a voltage of a cell to within a threshold tolerance. For example, the accuracy of the high precision voltage sensor is within a voltage threshold of +−0.1 mV.

Each high precision voltage sensor (220₁-220_{N}) is coupled to the Microprocessor 200. Each high precision voltage sensor (220₁-220_{N}) reports the sensed voltage to the Microprocessor 200.

The balancing circuitry includes a Balance Resistor (210₁-210_{N}). The Balance Resistor 210 is connected in parallel with the cell 215.

The balancing circuitry further includes a Switch (e.g., 205₁-205_{N}). A switch 205 is connected in series with the Balance Resistor 210. As depicted in FIG. 2, the Switch 205 is a MOSFET. However, other switching devices can be used such as a relay. The control terminal of the Switch is connected to the Microprocessor 200. For example, as depicted in FIG. 2, the gate of the MOSFET is connected to the Microprocessor 200.

The Microprocessor 200 controls the Switch 205 to open or close using a control signal input to the control terminal. The Switch 210 is used to enable or disable current balancing in the cell 215. When current balancing is required, the Microprocessor 200 controls the Switches (205₁-205_{N}) to enable current to pass through a respective Balance Resistor (210₁-210_{N}), e.g., Switch 205 is closed. The Balance current is identified as Balance Current 1-N in FIG. 2.

When the Switch 205 is opened, current balancing is disabled because of the open circuit; current cannot flow through the respective Balance Resistor (210₁-210_{N}).

The cells 215 are connected in series. The current in each cell flows from the negative terminal to the positive terminal during balancing. The cell current is identified as Cell 1 Current-Cell N Current using arrows pointing upward. The Switch 205, Balance Resistor 210 and high precision voltage sensor 220 is collectively referred to as the balancing circuitry.

The module 105 also includes a Module Positive Terminal 230 and a Module Negative Terminal 235. Current flows from the Module Negative Terminal 235 to the Module Positive Terminal 230.

The module 105 also includes a DC/DC converter 225 coupled to the Microprocessor 200 and the Module Positive Terminal 230 and the Module Negative Terminal 235. The DC/DC converter 225 receives as input, the series connection of all of the cells in the module 105. The DC/DC converter 225 outputs one or more low voltage regulated sources. The output(s) of the DC/DC converter 225 are used to power the Microprocessor 200, memory, high precision voltage sensors 220 and other balance control circuitry.

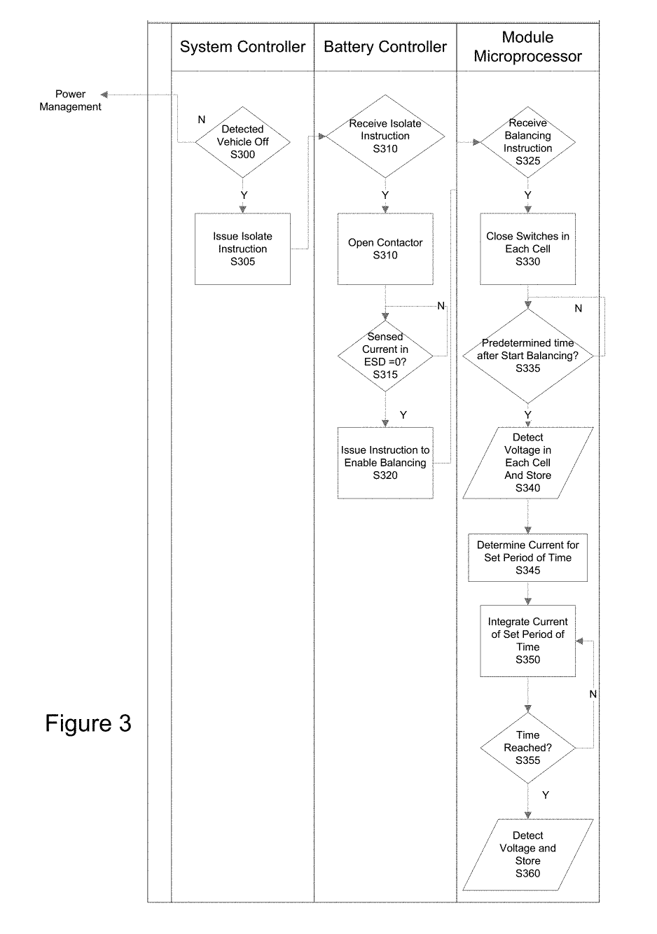

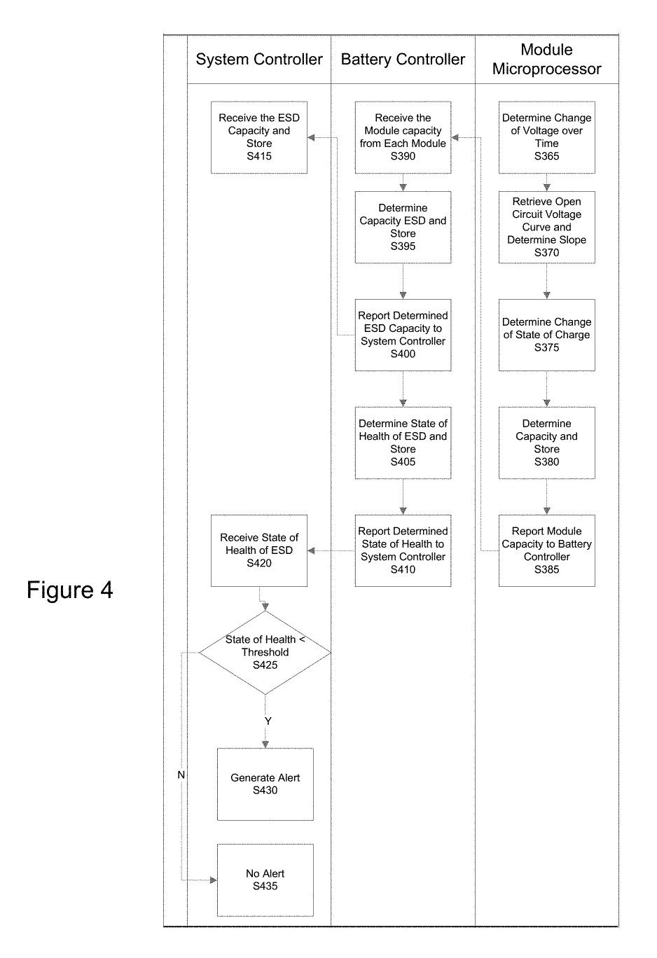

FIGS. 3 and 4 illustrate a method for determining a capacity of an energy storage device in accordance with aspects of the disclosure. FIGS. 3 and 4 also illustrate the interaction between the System Controller 600, the Battery Controller 120 and the Microprocessor 200.

Current balancing and the determination of the capacity of the Energy Storage Device occurs when the vehicle is shut down. At S300, the System Controller 600 determines if the vehicle has been shut down, e.g., off. For example, the System Controller 600 can determine that the vehicle is off when it receives a key-off signal. If the System Controller 600 detects that the vehicle is off (“Y” at S300), the System Controller 600 issues an instruction to the Battery Controller 120 to open the Contactor 115, e.g., isolate the Energy Storage Device 100 from the powertrain.

At S310, the Battery Controller 120 determines if an instruction is received from the System Controller 600. If the Battery Controller 120 receives the instruction from the System Controller 600 indicative of the vehicle being off, the Battery Controller 120 controls the Contactor 115 to open, thereby isolating the Energy Storage Device 100 from the powertrain (S310). The Contactor 115 changes from a closed state to an opened state. The Battery Controller 120 monitors the current sensed by the Current Sensor 110. The Battery Controller 120 waits for the sensed current to equal zero to enable current balancing for the cells. At S315, the Battery Controller 120 determines if the sensed current is zero. If, the Battery Controller 120 determines that the sensed current is zero (“Y” at S315), the Battery Controller 120 issues an instruction to the Microprocessor 200 for each module 105 to enable current balancing (S320). Alternatively, if the Battery Controller 120 determines that the current is not zero (“N” at S315), the Battery Controller 120 continues to wait.

S325-385 is performed by the Microprocessor 200 in each module 105. For purposes of the description, the steps will be described with respect to a single module. However, each module performs the steps approximately simultaneously.

At S315, the Microprocessor 200 determines if a balancing instruction is received from the Battery Controller 120. If, the Microprocessor 200 receives the balancing instruction from the Battery Controller 120 (“Y” at S325), the Microprocessor 200 enables balancing within each cell by closing Switches 205₁-205_{N}. The Switches change state from an opened state to a closed state. Thereby, current can flow across the respective Balance Resistor 210.

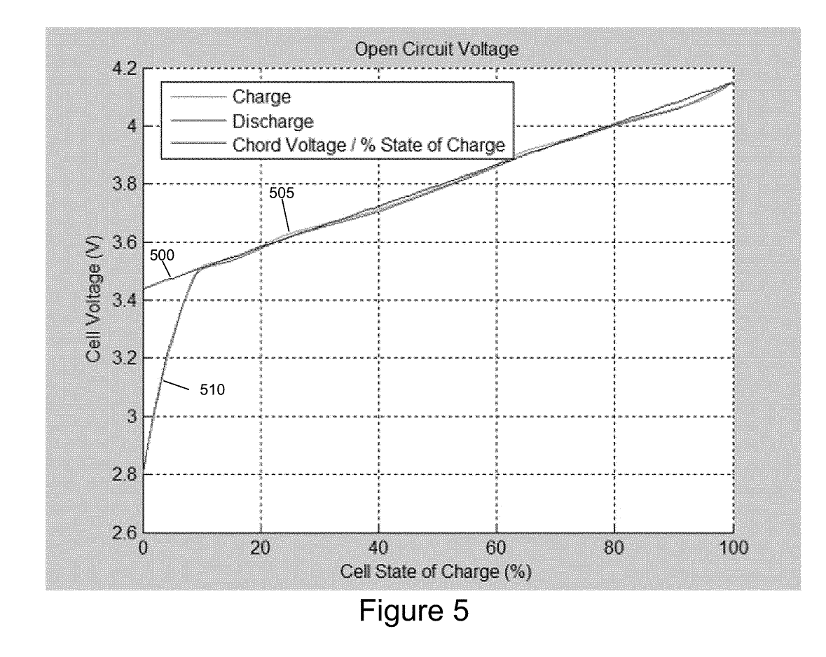

Batteries, such as Lithium ion batteries have an open circuit charge and discharge curve that correlates to a polarization of a cell. For example, after sufficient charge throughput the Battery will be biased to the charge open circuit voltage curve and after sufficient discharge throughput the battery will be biased to the discharge open circuit voltage curve. FIG. 5 illustrates an example of the charge 505 and discharge curve 510 for a cell. Curve 500 is a curve fit of the open circuit voltage indicating an average open circuit voltage over a typical SOC operating range of the cell.

The curves depicted in FIG. 5 are generated during manufacturing and testing of the Energy Storage Device, modules and cells. For example, the curves can be generated by discharging a cell at a constant current constant voltage CC-CV to a minimum allowed cell voltage, e.g., SOC=0%. The cell is then charged with the CC-CV profile to a maximum allowed cell voltage. During this time, the current is integrated into the module in order to record the AHr capacity of the cell. The cell is at SOC=100%. Afterwards, a fixed number of AHr is removed to induce a change in SOC. The cell then rests and the open circuit voltage is recorded along with a corresponding SOC. The process is repeated until SOC=0%. The discharge curve 510 is plotted using the determined values from the testing. The charged curve 505 is similarly created by starting a SOC=0% and stepped up to SOC=100%

In order to have the open circuit voltage curve biased to discharge, the Microprocessor 200, waits a predetermined time before beginning the capacity determination. In an aspect of the disclosure, the predetermined time is 30 minutes or more after the balancing of a cell is started.

The capacity is determined based on the total current drawn from each cell and corresponding voltage. The total current drawn from a cell includes a current of the microprocessor, I_{cpu}.

In an aspect of the disclosure, the Microprocessor 200 is modeled as a fixed power load, P_{cpu}. The module voltage is a sum of the voltages of the cell.

$${Voc}_{m} = {\sum }_{i = 1}^{N} {Voc}_{i} \qquad ( 1 )$$

The current of the microprocessor I_{cpu} is determined by the following equation:

$${I}_{cpu} = \frac{{P}_{cpu}}{{Voc}_{m}} \qquad ( 2 )$$

At S335, the Microprocessor 200 determines if the predetermined time after the start of the balancing has been reached. The Microprocessor 200 includes a clock or timer (not shown). If, the Microprocessor 200 determines that the predetermined time is reached (“Y” at S335), the Microprocessor 200 monitors the voltage of the cell Vocᵢ sensed by the High precision voltage sensors (220₁-220_{N}), for each of the cells (215₁-215_{N}). The voltage, for each cell, is stored in the memory of the Microprocessor 200 with a time.

At S340, the Microprocessor 200 determines the current for each cell for a preset period of time. The current for each cell is determined by the following equation:

I_{cell}_{_}ᵢ=I_{balance}_{_}ᵢ+I_{cpu} (3)

The balance current is determined by the following equation.

$${I}_{balance \_ i} = \frac{{Voc}_{i}}{{R}_{balance}} \qquad ( 4 )$$

The cell voltages Vocᵢ and in turn the module voltage Vocₘ is continuous monitored and updated for equations 2-4.

The determined currents and voltages are stored in memory of the Microprocessor 200.

At S350, the Microprocessor 200 integrates the determined current for the preset period of time (coulomb counting) using the following equation:

$$\frac{{dQ}_{i}}{dt} = \int {I}_{cell \_ i} dt \qquad ( 5 )$$

The integration begins when the first cell voltage for each cell is recorded (T=0). The integration ends at the end of the preset period of time (T=t).

At S355, the Microprocessor 200 determines if the end of the preset period of time has been reached. If, the Microprocessor 200 determines that the preset period of time has not ended (“N” at S355), the Microprocessor 200 continues to integrate the current for the preset period of time (returns to S350).

At S355, if the Microprocessor 200 determines that the preset period of time has ended (“Y” at S355), the Microprocessor 200 stops integrating the current and monitors the each cell's voltage, which is sensed by the high precision voltage sensors 220 and records each cell's voltage at the end of the preset period of time (S360).

At 5365, the Microprocessor 200 determines a change of voltage during the preset period of time for each cell. The change of voltage during the preset period of time for each cell is determined using the following equation.

$$\frac{{dVoc}_{i} ( t )}{dt} = {Voc}_{i} ( t ) - {Voc}_{i} ( 0 ) , . \qquad ( 6 )$$

where [symbol] is the voltage at the start of the preset period of time and Vocᵢ(t) is the voltage at the end of the preset period of time, for each cell.

At 5370, the Microprocessor 200 retrieves the open circuit voltage curve that is stored in the memory for the cells. An example, of the open circuit voltage curve is depicted in FIG. 5.

Using the retrieved open circuit voltage curve, the Microprocessor 200 determines the scope of the curve. Curve 500 is generated in advance and fitting the average open circuit voltage to y=mx+b. “M” can be stored in memory. Alternatively, discharge open circuit voltage curve can be analyzed in advance at discrete SOC point to generate a table of slopes. The table of slopes can be used by the Microprocessor 200 to extract the slope at a given SOC operating point.

The slope of the curve represents:

$$\frac{{dVoc}_{i}}{{dSoC}_{i}} . \qquad ( 7 )$$

At S375, the Microprocessor 200 determines a change in the state of charge for each cell. The change of state of charge is based on the slope of the curve and change in voltage during the preset period of time. The change in the state of charge for each cell is determined using the following equation:

$$\frac{{dSoC}_{i}}{dt} = \frac{\frac{{dVoc}_{i}}{dt}}{\frac{{dVoc}_{i}}{{dSoC}_{i}}} . \qquad ( 8 )$$

The preset period of time needs to be a sufficient time to avoid dividing by zero. In an aspect of the disclosure, the preset period of time is determined based on the slope of the open circuit voltage curve. The preset period of time is inversely related to the slope.

At S380, the Microprocessor 200 determines the capacity of each cell. The capacity of each cell is determined based on the integrated current and the change in the state of charge. The capacity of each cell is determined using the following equation:

$${C}_{i} = \frac{\frac{{dQ}_{i}}{dt}}{\frac{{dSoC}_{i}}{dt}} . \qquad ( 9 )$$

The capacity for each cell is stored in the memory of the Microprocessor 200. The Microprocessor 200 also determines the capacity of the module 105. The capacity of the module is equal to the capacity of the cell with the lowest determined capacity. The module capacity is stored in the memory of the Microprocessor 200.

At S385, the Microprocessor 200 reports the determined module capacity to the Battery Controller. The controllers/microprocessors communicate with each other via a Control Area Network (CAN) bus. The CAN bus is a standard vehicle digital communication network and will not be described herein. Alternatively, other digital communication infrastructure can be used.

As described above, the Battery Controller 120 receives the module capacity from each of the Microprocessors 200 in the plurality of modules (S390). The module capacity for each module 105 is stored in the memory of the Battery Controller 120.

At 5395, the Battery Controller 120 determines the capacity of the Energy Storage Device 100 from the received module capacities. The capacity of the Energy Storage Device is equal to the capacity of the module with the lowest determined capacity. The capacity of the Energy Storage Device is stored in the memory of the Battery Controller 120 in association with a time. In an aspect of the disclosure, the determined capacity is stored as a table with the time of determination.

At 5400, the Battery Controller 120 reports the determined capacity for the Energy Storage Device 100 to the System Controller 600. The System Controller 600 stores the capacity of the Energy Storage Device 100 for later use (S415). The System Controller 600 uses the determined capacity stored to control power to and from the Energy Storage Device 100 the next time the vehicle is turned on.

At 5405, the Battery Controller 120 determines a state of health for the Energy Storage Device. In an aspect of the disclosure, the state of health (“SOH”) is a metric indicative of the relationship between the determined capacity and the initial nominal capacity for the Energy Storage Device.

For example, the SOH can be determined by the following equation:

$$SOH = \frac{Initial Nominal Capacity \text{-Determined Capacity}}{Initial Nominal Capacity} \qquad ( 10 )$$

In another aspect of the disclosure, the state of health is a metric indicative of the change in the capacity between two successive capacity determinations.

For example, the SOH can be determined by the following equation:

SOH=Determined Capacity(T2)−Determined Capacity(T1) (11).

The Battery Controller 120 stores the SOH of the Energy Storage Device in memory. In an aspect of the disclosure, the determined SOH is stored as a table with the time of determination. In another aspect of the disclosure, the Battery Controller 120 determines the SOH using both equations 10 and 11 and separately stores the two SOH values.

In another aspect of the disclosure, the Battery Controller 120 can compare the determined capacities for each module with other modules. If the module capacity for a given module 105 is significantly below the other modules, the Battery Controller 120 reports to the System Controller 600 an indication that a module capacity for the module may be detective and replaced.

At 5410, the Battery Controller 120 reports the SOH to the System Controller 600.

At 5420, the System Controller 600 receives the SOH from the Battery Controller 120 and stores the same in memory.

When the vehicle is subsequently turn on, the System Controller 600 retrieves the SOH from memory. The System Controller 600 compares the SOH with a threshold (S425). In an aspect of the disclosure, if the SOH of the Energy Storage Device is less than the threshold (“Y”), the System Controller 600 generates an alert (S430). The generated alert can be displayed on a panel of the vehicle to alert the driver that the Energy Storage Device 100 requires maintenance or must be replaced. In another aspect of the disclosure, multiple thresholds can be used. For example, a first threshold can be used as an early warning that the capacity of the Energy Storage Device 100 should be watched. A second threshold can be used as a indicated that the capacity of the Energy Storage Device 100 is below a required value and the Energy Storage Device 100 should be replaced. The second threshold is lower than the first threshold.

If the SOH of the Energy Storage Device is not less than the threshold (“N”), the System Controller 600 does not generate the alert (S435).

In another aspect of the disclosure, if equation 11 is used to determine the SOH, the comparison is if the determined SOH is greater than the threshold. If the determined SOH is greater than the threshold, than the change in the capacity is large, which may indicate a defective circuit. Additionally, it may indicate that the Energy Storage Device 100 was overused in the previous drive cycle.

If at S300, the System Controller 600 does not detect that the vehicle is off, e.g., the vehicle is on, the System Controller 600 execute power management and regulation as will be described later for both parallel and series hybrid vehicles.

FIG. 6 illustrates a block diagram of a parallel hybrid electric vehicle in accordance with aspects of the disclosure. The parallel hybrid electric vehicle includes an Energy Storage Device 100 as described above and System Controller 600 as partially described above. The System Controller 600 includes a Clutch Control Assembly for controlling a clutch assembly 605. The System Controller 600 includes an inverter (not shown). The parallel hybrid electric vehicle includes internal combustion engine (Engine) 640 coupled to an integrated starter/generator (ISG) 615 by way of a clutch assembly 605. The ISG 615 is mechanically coupled to a transmission 615 by torque converter 620.

The transmission system 625 provides driver-controlled or vehicle computer-controlled gear ratio selection from among at least one gear ratio depending on velocity, torque and acceleration requirements. The parallel hybrid electric vehicle also includes user interfaces such as a brake 630 and a pedal 635. The pedal 635 is used by the operator to increase the torque demand and the brake is used by the operator to decrease the torque demand.

The total torque applied to the transmission system can be a combination of the torque provided by both the engine 640 and the ISG 615 when the clutch assembly 605 is closed and the ISG 615 alone when the clutch assembly 605 is open.

The System Controller 600 controls the parallel hybrid electric vehicle. The System Controller 600 determines the torque sharing or apportioning between engine 640 and the ISG 615, i.e., the amount of torque provided by the engine 640 and the ISG 615. The determination is based on the required or demanded torque by the operator of the vehicle and the state of charge of the Energy Storage Device 100.

The System Controller 600 determines the state of charge of the Energy Storage Device 100. The state of charge of the Energy Storage Device 100 is determined based on the current charge level in the Energy Storage Device 100 versus the maximum capacity of the Energy Storage Device 100. When determining the SOC of the battery, the System Controller 600 uses the latest determined capacity as described above as the maximum capacity of the Energy Storage Device 100. In another aspect of the disclosure, the Battery Controller 120 can compute the SOC using the measured values.

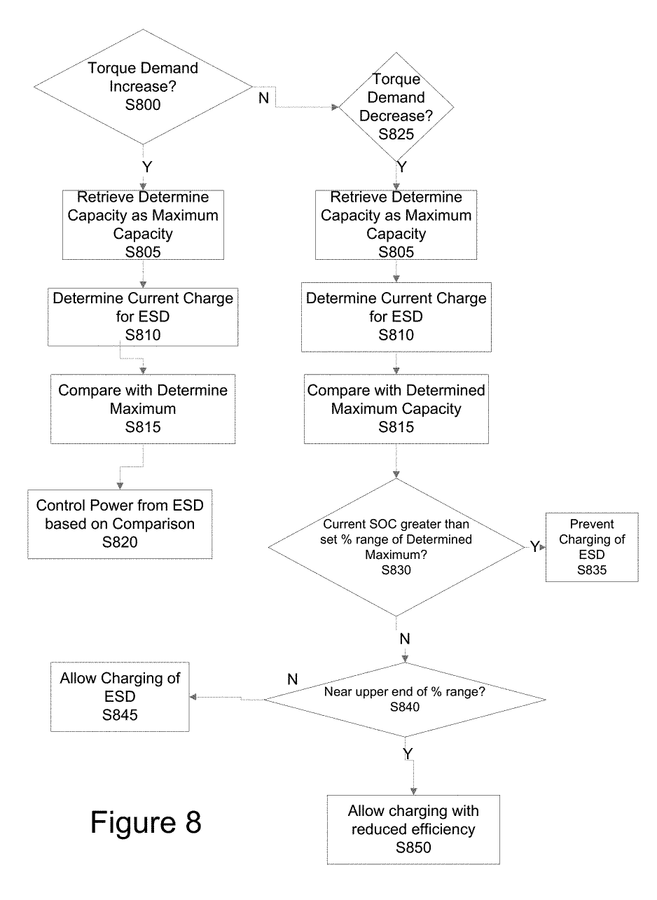

FIG. 8 illustrates a method for controlling power to and from an energy storage device using the determined capacity in accordance with aspects of the disclosure.

The following is a description of an example of the power regulation in a parallel hybrid electric vehicle in accordance with aspects of the disclosure.

The System Controller 600 determines if a change in the demanded torque is requested or sensed. At S800, the System Controller 600 determines if there is a request for an increase in the total torque. For example, the operator commands an increase in torque via the pedal 635. If, the System Controller 600 determined there is an request for increase (“Y” at S800), the System Controller 600 determines the current charge level of the Energy Storage Device 100 (S810) and retrieves the latest determined capacity of the Energy Storage Device (S805). At S815, the System Controller 600 calculates a SOC of the Energy Storage device using determined capacity as the maximum capacity of the Energy Storage Device 100 (S815). The SOC is determined using the following equation:

SOC=Current Charge/Determined Capacity (12).

At 5820, the power from the Energy Storage Device 100 is controlled based on the determined SOC. The System Controller 600 adjusts the torque sharing between the engine 640 and ISG 615 based on the determined SOC. In an aspect of the disclosure, the SOC of the Energy Storage Device is maintained to be between 20%-80% the parallel hybrid electric vehicle. Therefore, if the SOC is closer to the lower end of the range, the System Controller 600 uses less power from the Energy Storage Device 100. In other words, the System Controller 600 will adjust the torque sharing between the between the Engine 640 and ISG 615 to increase the torque supplied by the Engine 640 and decrease the torque supplied by the ISG 615. Additionally, the System Controller 600 may disengage the clutch to isolate the Engine 640 from the transmission system.

If the SOC is closer to the upper end of the range, the System Controller 600 uses more power from the Energy Storage Device 100. In other words, the System Controller 600 will adjust the torque sharing between the between the Engine 640 and ISG 615 to decrease the torque supplied by the Engine 640 and increase the torque supplied by the ISG 615.

At S825, the System Controller 600 determines if there is a request for a decrease in the total torque or senses deceleration. For example, the operator commands a decrease in torque via the brake 630. Additionally, when the vehicle is coasting, the System Controller 600 determines that there is a request for a decrease in the total torque.

If the System Controller 600 determines that there is a request for decrease in the torque (“Y” at S825), the System Controller 600 retrieves the latest determined capacity of the Energy Storage Device (S805). The System Controller 600 determines the current charge level of the Energy Storage Device 100. (S810) At S815, the System Controller 600 calculates a SOC of the Energy Storage device using determined capacity as the maximum capacity of the Energy Storage Device 100 using equation 12.

The System Controller 600 determines whether to allow the ISG 615 to charge the Energy Storage Device 100 using regenerative energy. At 5830, the System Controller determined if the calculated SOC (using the determined capacity as the maximum capacity) is greater than a preset maximum. As noted above, for the parallel hybrid electric vehicle, the SOC is maintained between 20%-80%. Therefore, the preset maximum can be set to 80%.

To prevent overcharging, when the SOC is above the preset maximum (“Y” at S835), regenerative charging (regenerative braking) of the Energy Storage Device 100 is prevented (S835). In an aspect of the invention, regenerative charging is prevented by removing a negative torque command from the ISG 615. In another aspect of the disclosure, the Engine 640 can be used as a load. In yet another aspect of the disclosure a combination of both can be used. For example, the regenerative torque can be loaded to the Engine 640 until the Engine 640 reaches a maximum speed and then use the mechanical braking system to decelerate the vehicle.

Additionally, the System Controller may disengage the clutch assembly to isolate the Engine 640 from the Transmission System.

If the SOC is less than the preset maximum, the System Controller 600 determines whether the SOC is near the upper end of the predetermined range of 20%-80%. For example, if the SOC is above 75% (S840), the System Controller 600 deems the SOC to be near the upper end of the predetermined range. If the SOC is near the upper end of the range (“Y” at S840), the System Controller 600 allows regenerative charging of the Energy Storage Device 100, but reduces the power flow into the battery. For example, the System Controller 600 can use the PWM duty cycle to request less power. In an aspect of the disclosure, the System Controller 600 commands a negative torque from the ISG 615. The ISG 615 operates as an electric generator in order to recoup regenerative braking energy for recharging.

If at S840, the System Controller 600 determines that the SOC is not near the upper range (“N” at S840), the System Controller 600 allows regenerative charging of the Energy Storage Device 100, at full rating. In an aspect of the disclosure, the System Controller 600 commands a negative torque from the ISG 615. The ISG 615 operates as an electric generator in order to recoup regenerative braking energy for recharging.

If the torque demand does not change, the torque sharing may also be adjusted based on the current SOC, in a similar manner as described above.

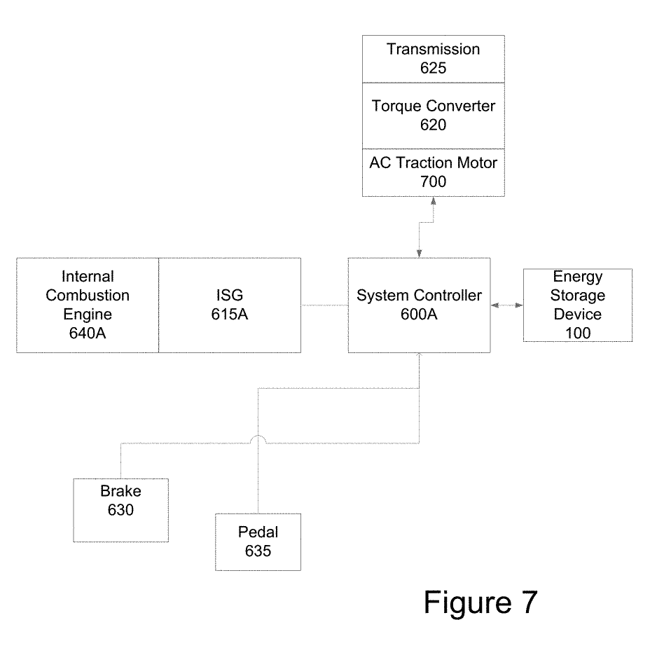

FIG. 7 illustrates a block diagram of a series hybrid electric vehicle in accordance with aspects of the disclosure. The series hybrid electric vehicle includes an Energy Storage Device 100 as described above and System Controller 600A as partially described above. The series hybrid includes an Internal Combustion Engine 640A (Engine) directly coupled to the ISG 615A. The ISG 615A is coupled to the System Controller 600A. The System Controller 600A is coupled to an AC Traction Motor 700. The AC Traction Motor 700 is coupled to the Transmission System 625 via the torque converter 620. The AC Traction Motor 700 and Engine 640A can be separately operated. The Engine 640A is isolated from the Transmission System 625.

The Transmission System 625 provides driver-controlled or vehicle computer-controlled gear ratio selection from among at least one gear ratio depending on velocity, torque and acceleration requirements. The series hybrid electric vehicle also includes user interfaces such as a brake 630 and a pedal 635. The pedal 635 is used by the operator to increase the torque demand and the brake is used by the operator to decrease the demanded torque.

When the Engine 640A is on, the Engine 640A supplies power to the ISG 615 to acts a generator. The energy from the generator is supplied to the AC Traction Motor 700 via the System Controller 600A.

Additionally, power from the Energy Storage Device 100 is supplied to the AC Traction Motor 700 via the System Controller 600A. The System Controller 600A includes an inverter (not shown).

If needed, power from the ISG 615A, when acting as a generator can be supplied to the Energy Storage Device 100 for recharging.

The following is a description of an example of the power regulation in a series hybrid electric vehicle in accordance with aspects of the disclosure with reference to FIG. 8.

The System Controller 600A determines if a change in the demanded torque is requested or sensed. At S800, the System Controller 600A determines if there is a request for an increase in the total torque. For example, the operator commands an increase torque via the pedal 635. If, the System Controller 600A determined there is an request for increase (“Y” at S800), the System Controller 600A determines the current charge level of the Energy Storage Device (S810) and retrieves the latest determined capacity of the Energy Storage Device (S805). At S815, the System Controller 600A calculates a SOC of the Energy Storage Device using determined capacity as the maximum capacity of the Energy Storage Device 100 (S815). The SOC is determined using equation 12.

At 5820, the power from the Energy Storage Device 100 is controlled based on the determined SOC. In as aspect of the disclosure, the SOC of the Energy Storage Device is maintained between 20%-60% for a series hybrid electric vehicle.

If the SOC is closer to the lower end of the range, the System Controller 600A uses less power from the Energy Storage Device 100. In other words, the System Controller 600A instruct the Engine 640A to input to the ISG 615A. The ISG 615A will act as a generator, e.g., the System Controller 600A will command a positive torque and the power will be supplied to the AC Traction Motor 700 via the System Controller 600A. The generated power by the ISG 615A will also be supplied to the Energy Storage Device 100 for recharging via the System Controller 600A (and its inverter).

If the SOC is closer to the upper end of the range, the System Controller 600A uses more power from the Energy Storage Device 100. In other words, the System Controller 600A instructs the Engine 640A to idle. A positive torque command to the ISG 615A is stopped. Power from the Energy Storage Device 100 is supplied to the AC Traction Motor 700 via the System Controller 600A.

At S825, the System Controller 600A determines if there is a request for a decrease in the total torque or senses deceleration. For example, the operator commands a decrease in torque via the brake 630. Additionally, when the vehicle is coasting, the System Controller 600A determines that there is a request for a decrease in the total torque.

The System Controller 600A determined there is a request for decrease in torque (“Y” at S825), the System Controller 600A retrieves the latest determined capacity of the Energy Storage Device (S805). The System Controller 600A determines the current charge level of the Energy Storage Device. (S810) At S815, the System Controller 600A calculates a SOC of the Energy Storage device using determined capacity as the maximum capacity of the Energy Storage Device 100 using equation 12.

The System Controller 600A determines whether to allow the AC Traction Motor 700 to charge the Energy Storage Device 100. At 5830, the System Controller determines if the calculated SOC (using the determined capacity as the maximum capacity) is greater than a preset maximum. As noted above, for the series hybrid electric vehicle the SOC is maintained between 20%-60%. Therefore, the preset maximum can be set to 60%.

To prevent overcharging, when the SOC is above the preset maximum (“Y” at S835), the Energy Storage Device 100 is not charge (S835). If the Engine 640A is on or the ISG 615A is commanded for a torque, the System Controller 600A issues commands reducing the torque from the ISG 615A and/or output from the Engine 640A. For example, depending on the torque needed, the Engine 640A may idle.

If the SOC is less than the preset maximum, the System Controller 600A determines whether the SOC is near the upper end of the predetermined range of 20%-60%. For example, if the SOC is above 55% (S840), the System Controller 600A deems the SOC to be near the upper end of the predetermined range. If the SOC is near the upper end of the range (“Y” at S840), the System Controller 600A allows recharging of the Energy Storage Device 100, but at a reduced power. In an aspect of the disclosure, power from the AC Traction Motor 700 is recoup to charge the Energy Storage Device 100.

If at S840, the System Controller 600A determines that the SOC is not near the upper range, (“N” at S840), the System Controller 600A allows charging of the Energy Storage Device 100, at full rating.

If the torque demand does not change, the power to and from the Energy Storage Device may be also adjusted based on the current SOC, in a similar manner as described above.

In accordance with aspects of the disclosure, the System Controller 600/600A, for either a series or parallel hybrid vehicle uses the latest determined capacity for the Energy Storage Device, which was determined during current balancing while the vehicle is off, for power management, e.g., power to and from the Energy Storage device. By using the latest determined capacity (determined in accordance with aspects of the disclosure) for power management, the life of the Energy Storage Device can be extended. Additionally, by using the latest determined capacity (determined in accordance with aspects of the disclosure) for power management, sudden failure of the Energy Storage Device can be avoided.

Various aspects of the present disclosure may be embodied as a program, software, or computer instructions embodied or stored in a computer or machine usable or readable medium, or a group of media which causes the computer or machine to perform the steps of the method when executed on the computer, processor, and/or machine. A program storage device readable by a machine, e.g., a computer readable medium, tangibly embodying a program of instructions executable by the machine to perform various functionalities and methods described in the present disclosure is also provided, e.g., a computer program product.

The computer readable medium could be a computer readable storage device or a computer readable signal medium. A computer readable storage device, may be, for example, a magnetic, optical, electronic, electromagnetic, infrared, or semiconductor system, apparatus, or device, or any suitable combination of the foregoing; however, the computer readable storage device is not limited to these examples except a computer readable storage device excludes computer readable signal medium. Additional examples of the computer readable storage device can include: a portable computer diskette, a hard disk, a magnetic storage device, a portable compact disc read-only memory (CD-ROM), a random access memory (RAM), a read-only memory (ROM), an erasable programmable read-only memory (EPROM or Flash memory), an optical storage device, or any appropriate combination of the foregoing; however, the computer readable storage device is also not limited to these examples. Any tangible medium that can contain, or store, a program for use by or in connection with an instruction execution system, apparatus, or device could be a computer readable storage device.

A computer readable signal medium may include a propagated data signal with computer readable program code embodied therein, such as, but not limited to, in baseband or as part of a carrier wave. A propagated signal may take any of a plurality of forms, including, but not limited to, electro-magnetic, optical, or any suitable combination thereof. A computer readable signal medium may be any computer readable medium (exclusive of computer readable storage device) that can communicate, propagate, or transport a program for use by or in connection with a system, apparatus, or device. Program code embodied on a computer readable signal medium may be transmitted using any appropriate medium, including but not limited to wireless, wired, optical fiber cable, RF, etc., or any suitable combination of the foregoing.

The terms “System Controller”, “Battery Controller” and “Microprocessor” as may be used in the present disclosure may include a variety of combinations of fixed and/or portable computer hardware, software, peripherals, and storage devices. The System Controller“, “Battery Controller” and “Microprocessor” may include a plurality of individual components that are networked or otherwise linked to perform collaboratively, or may include one or more stand-alone components.

In another aspect of the disclosure, “System Controller”, “Battery Controller” and “Microprocessor” can be any processing hardware such as a CPU or GPU. In another aspect of the disclosure, an ASIC, FPGA, a PAL and PLA can be used as the processing hardware.

The terminology used herein is for the purpose of describing particular embodiments only and is not intended to be limiting the scope of the disclosure and is not intended to be exhaustive. Many modifications and variations will be apparent to those of ordinary skill in the art without departing from the scope and spirit of the disclosure.

What is claimed is:

1. A method comprising:
enabling balancing of current in a plurality of cells of a battery module by controlling a switch within each cell, each cell including a balance resistor;
storing, in a memory of a battery microprocessor, for each cell of the plurality of cells, a voltage of the respective cell at a predetermined time after the balancing is enabled, the voltage is sensed using a precision voltage sensor;
determining, for each cell of the plurality of cells, a cell current, for a predetermined period of time beginning at the predetermined time after the balancing is enabled;
detecting, for each cell of the plurality of cells, a voltage of the respective cell at the end of the predetermined period of time;
determining, for each cell of the plurality of cells, a change in a state of charge of the respective cell based on a change in the voltage over the predetermined period of time and a slope of an open circuit voltage curve;
determining, for each cell of the plurality of cells, a cell capacity based on the change in the state of charge and the determined cell current for the predetermined period of time;
storing, in the memory of the battery microprocessor, for each cell, the determined cell capacity; and
transmitting, a module capacity to a battery controller for an energy storage device, wherein the lowest determined cell capacity for the plurality of cells, is the module capacity for the battery module.

2. The method of claim 1, wherein the battery module is one of a plurality of battery modules in the energy storage device, and the capacity for each of the plurality of battery modules is determined.

3. The method of claim 2, further comprising determining a capacity for the energy storage device, wherein the capacity for the energy storage device is the lowest determined module capacity for the plurality of modules.

4. The method of claim 3, further comprising transmitting the capacity for the energy storage device to a system controller, wherein the system controller controls power to and from the energy storage device based on the capacity for the energy storage device.

5. The method of claim 3, further comprising determining a state of health for the energy storage device.

6. The method of claim 5, further comprising generating an alert if the state of health is below a threshold.

7. The method of claim 1, wherein the open circuit voltage curve is stored in the memory of the battery microprocessor.

8. The method of claim 1, the predetermined period of time is determined based on the slope of the open circuit voltage curve.

9. The method of claim 1, further comprising opening a switch between the energy storage device and a powertrain thereby electrically isolating the energy storage device upon receipt of a key-off signal.

10. A battery module for an energy storage device comprising:
a plurality of cells,
balancing circuitry associated with each cell, the balancing circuitry comprising a balance resistor, a balance switch and a precision voltage sensor, the balance switch being configured to close to enable current balancing between the plurality of cells and open to disable the current balancing, the balance switch being connected in series with the balance resistor, the precision voltage sensor being configured to detect a voltage of the cell; and
a microprocessor including a memory, the memory having a stored open circuit voltage curve indicating a relationship between a voltage of a respective cell and a state of charge for the respective cell,
the microprocessor configured to:
receive a signal instructing current balancing for the plurality of cells from a battery microprocessor for the energy storage device;
control the balance switch associated with each cell to close to enable current balancing;
store in the memory, a first voltage of each of the plurality of cells, the first voltage being detected by a respective precision voltage sensor at a predetermined time after the balancing is enabled;
determine, for each cell of the plurality of cells, a cell current, for a predetermined period of time beginning at the predetermined time after the balancing is enabled;
store in the memory, a second voltage of each of the plurality of cells, the second voltage being detected by the respective precision voltage sensor at the end of the predetermined period of time;
determine, for each cell of the plurality of cells, a change in a state of charge of the respective cell based on a slope of the open voltage curve stored in memory and a change in the voltage over the predetermined period of time determined from the stored first voltage and the second voltage;
determine, for each cell of the plurality of cells, a cell capacity based on the change in the state of charge and the determined cell current for the predetermined period of time;
store, in the memory, for each cell, the determined cell capacity; and
transmit, a module capacity to the battery microprocessor, wherein the lowest determined cell capacity for the plurality of cells, is the module capacity for the battery module.

11. An energy storage device comprising:
a switch configured to either electrically isolate the energy storage device from a powertrain of a vehicle or electrically couple the energy storage device to the powertrain;
a battery current sensor configured to detect current in the energy storage device;
a battery microprocessor configured to control the switch to open to electrically isolate or close to electrically couple based on a signal received from a system controller, wherein when the battery microprocessor receives a signal from the system controller that the vehicle is off, the battery microprocessor controls the switch to open, the battery microprocessor monitors the current detected by the battery current sensor; and
a plurality of battery modules, each of the plurality of modules comprising a plurality of cells,
each cell is associated with balancing circuitry, the balancing circuitry comprising:
a balance resistor,
a balance switch; and
a precision voltage sensor, the balance switch being configured to close to enable current balancing between the plurality of cells and open to disable the current balancing, the balance switch being connected in series with the balance resistor, the precision voltage sensor being configured to detect a voltage of the cell,
each of the plurality of battery modules further comprising a microprocessor including a memory, the memory having a stored open circuit voltage curve indicating a relationship between a voltage of a respective cell and state of charge for the respective cell, the plurality of battery modules being coupled to the battery microprocessor, wherein, after the battery microprocessor determines that the current of the energy storage device is zero, the battery microprocessor issues an instruction to the microprocessor in each of the plurality of modules to enable current balancing, and
wherein the microprocessor in each of the plurality of modules is configured to:
receive the instruction from the battery microprocessor to enable current balancing for the plurality of cells;
control the balance switch associated with each cell to close to enable current balancing;
store in the memory, a first voltage of each of the plurality of cells, the first voltage being detected by a respective precision voltage sensor at a predetermined time after the balancing is enabled,
determine, for each cell of the plurality of cells, a cell current, for a predetermined period of time beginning at the predetermined time after the balancing is enabled;
store in the memory, a second voltage of each of the plurality of cells, the second voltage being detected by the respective precision voltage sensor at the end of the predetermined period of time;
determine, for each cell of the plurality of cells, a change in a state of charge of the respective cell based on a slope of the open voltage curve stored in memory and a change in the voltage over the predetermined period of time determined from the stored first voltage and the second voltage;
determine, for each cell of the plurality of cells, a cell capacity based on the change in the state of charge and the determined cell current for the predetermined period of time;
store, in the memory, for each cell, the determined cell capacity; and
transmit, a module capacity to the battery microprocessor, wherein the lowest determined cell capacity for the plurality of cells, is the module capacity for the battery module, and wherein the battery microprocessor is further configured to store each of the transmitted module capacities in a memory of the battery microprocessor and determine a capacity for the energy storage device, the capacity for the energy storage device is the lowest determined module capacity for the plurality of modules, and transmit the determined battery capacity to the system controller.

12. An energy storage device of claim 11, wherein the battery microprocessor is further configured to determine a state of health for the energy storage device.

13. A power management system for a vehicle comprising:
a system controller configured to control power to and from an energy storage device, the system controller is coupled to the energy storage device,
the energy storage device comprising:
a switch configured to either electrically isolate the energy storage device from a powertrain of a vehicle or electrically couple the energy storage device to the powertrain;
a battery current sensor configured to detect current in the energy storage device;
a battery microprocessor configured to control the switch to open to electrically isolate or close to electrically couple based on a signal received from the system controller; and
a plurality of battery modules,
wherein when the vehicle is turned off, the system controller is configured to issue a signal to the battery microprocessor,
wherein, when the battery microprocessor receives the signal from the system controller that the vehicle is off, the battery microprocessor controls the switch to open, and the battery microprocessor monitors the current detected by the battery current sensor, and
wherein, each of the plurality of battery modules comprises a plurality of cells,
each cell is associated with balancing circuitry comprising:
a balance resistor,
a balance switch, and
a precision voltage sensor, the balance switch being configured to be closed to enable current balancing between the plurality of cells and opened to disable the current balancing, the balance switch being connected in series with the balance resistor, the precision voltage sensor being configured to detect a voltage of the cell; and
each of the plurality of battery modules further comprising a microprocessor including a memory, the memory having a stored open circuit voltage curve indicating a relationship between a voltage of a respective cell and state of charge for the respective cell, the plurality of battery modules being coupled to the battery microprocessor, wherein, after the battery microprocessor determines that the current of the energy storage device is zero, the battery microprocessor issues an instruction to the microprocessor in each of the plurality of modules to enable current balancing, and
wherein the microprocessor in each of the plurality of modules is configured to:
receive the instruction from the battery microprocessor to enable current balancing for the plurality of cells;
control the balance switch associated with each cell to close to enable current balancing;
store in the memory, a first voltage of each of the plurality of cells, the first voltage being detected by a respective precision voltage sensor at a predetermined time after the balancing is enabled,
determine, for each cell of the plurality of cells, a cell current, for a predetermined period of time beginning at the predetermined time after the balancing is enabled;
store in the memory, a second voltage of each of the plurality of cells, the second voltage being detected by the respective precision voltage sensor at the end of the predetermined period of time;
determine, for each cell of the plurality of cells, a change in a state of charge of the respective cell based on a slope of the open voltage curve stored in memory and a change in the voltage over the predetermined period of time determined from the stored first voltage and the second voltage;
determine, for each cell of the plurality of cells, a cell capacity based on the change in the state of charge and the determined cell current for the predetermined period of time;
store, in the memory, for each cell, the determined cell capacity; and
transmit, a module capacity to the battery microprocessor, wherein the lowest determined cell capacity for the plurality of cells, is the module capacity for the battery module,
wherein the battery microprocessor is further configured to:
store each of the transmitted module capacities in a memory of the battery microprocessor;
determine a capacity for the energy storage device, the capacity for the energy storage device is the lowest determined module capacity for the plurality of modules; and
transmit the determined battery capacity to the system controller, and
wherein the system controller is further configured to:
store the determined battery capacity received from the battery microprocessor, wherein when the vehicle is turned on subsequently, the system controller is further configured to control power to and from the energy storage device using the determined battery capacity as a maximum capacity for the energy storage device to maintain the energy storage device within a predetermined range of the maximum capacity.

14. The power management system of claim 13, wherein the battery microprocessor is further configured to determine a state of health for the energy storage device and transmit the determined state of health for the energy storage device to the system controller.

15. The power management system of claim 14, wherein the system controller is further configured to generate an alert when the determined state of health for the energy storage device is below of predetermined threshold.

16. The power management system of claim 14, wherein the state of health for the energy storage device is based on a difference between the determined capacity of the energy storage device and a nominal initial capacity of the energy storage device at installation.

17. The power management system of claim 16, wherein the state of health and the capacity of the energy storage device is stored in the memory of the battery microprocessor and associated with a time stamp.

18. The power management system of claim 13, wherein the precision voltage sensor has a tolerance less than a voltage threshold.

19. The power management system of claim 18, wherein the voltage threshold is +−0.1 mV.
